(19) United States
(12) Patent Application Publication
(10) Pub. No.: US 2022/0405346 A1
(43) Pub. Date: Dec. 22, 2022

(54) METHOD FOR DETERMINING THE STATE OF A SYSTEM AND DEVICE IMPLEMENTING SAID METHODS

(71) Applicants: COMMISSARIAT À L'ÉNERGIE ATOMIQUE ET AUX ÉNERGIES ALTERNATIVES, PARIS (FR); UNIVERSITE DE SAVOIE MONT BLANC, CHAMBERY CEDEX (FR); CENTRE NATIONAL DE LA RECHERCHE SCIENTIFIQUE, PARIS (FR)

(72) Inventors: Sylvain LESPINATS, GRENOBLE CEDEX 09 (FR); Benoît COLANGE, GRENOBLE CEDEX 09 (FR); Denys DUTYKH, CHAMBERY (FR); Laurent VUILLON, CHAMBERY (FR)

(21) Appl. No.: 17/770,518

(22) PCT Filed: Oct. 20, 2020
(86) PCT No.: PCT/EP2020/079447

§ 371 Date: Apr. 20, 2022

(30) Foreign Application Priority Data
Oct. 22, 2019 (FR) FR1911780

(51) Int. Cl. G06F 17/11

(52) U.S. Cl. CPC G06F 17/11

(57) ABSTRACT

A method for determining the state of a system among a plurality of states, includes acquiring values of a reference physical quantity of the system corresponding to a plurality of points in an original space, each value being paired with one point of the plurality of points and with one state of the system; embedding a portion of the points in a representation space, the representation space being in bijection with a sub-variety of the original space, each point in the representation space being paired with one state; determining a pairing function that pairs any position of the original space with a position in the representation space; determining the position in the representation space of a point of the original space paired with an acquired value, and determining the state of the system from the position of the point paired with the acquired value in the representation space.

### TECHNICAL FIELD OF THE INVENTION

The technical field of the invention is that of characterising the state of a system.

The present invention relates to a method for determining the state of a system and in particular a method for determining the state of a system using an embedding. The invention also relates to a device implementing said method.

### TECHNOLOGICAL BACKGROUND OF THE INVENTION

In many technological fields, it is sometimes necessary to analyse a large number of measurements of a physical quantity that can be observed of a system in order to pair them with different states of said system. As each measurement of a physical quantity of a system can be paired with a state of said system, it is then possible to wonder about the relative organisation of these states.

However, in certain cases, the physical quantity measured can be represented only in a space that has a large number of dimensions. It is possible for example to mention the case of recognising expressions of the face, recognising handwritten characters or the monitoring of batteries using acoustic measurements. In light of this high number of dimensions, one is often led to project said values in a space of smaller dimension in order to facilitate the analysis thereof and to be able to more easily pair each measured value with a state of the system. A “map” of the states of the system is then sometimes spoken of. A large number of methods exist in this framework; they are generally grouped together under the term of dimensionality reduction. Generally, the construction of such a representation consumes relatively much in terms of calculation resources, but this does not generally pose a problem given that the latter is implemented only once when it is sought to analyse the measurements a posteriori.

On the other hand, if it were sought to deduce the state of a system via a new measurement of the reference physical quantity through this type of solutions, it would be necessary to project this measured value in the space of smaller dimensions before being able to pair the measured value with a state of the system. Yet, generally, the methods for projecting used do not make it possible to project a single value coming from a new measurement, but on the contrary require taking the set of values of the physical quantity measured (the learning values and the newly-measured value or values) in order to be able to carry out a new projection. In light of the calculation resources required for such an operation, it is generally difficult to carry out the monitoring, for example in real time, of a system by using a projection technique. So, these methods are confined to the exploration of past data, and are only very rarely used in other cases. In order to reduce the complexity of the step of projecting a new measured value, techniques that are specific to certain methods of projection make it possible to project a single point on the resulting map. But through their attachment to a specific method of projection, they are not versatile.

In order to partially solve these problems, patent application FR1663011 proposes to use two meshings: a first meshing called projection meshing and a second meshing, called original meshing, in bijection with the projection meshing. This solution of course makes it possible to reduce calculation times, but determining meshes remains expensive. In addition, in light of the edge effects, the projection of the points located close to the boundary of the sub-variety in the representation space is not always reliable.

There is therefore a need for a method of dimensionality reduction that makes it possible to overcome the determining of the meshing for the projection of the data from the original space to the representation space. There is also a need for a method of dimensionality reduction that makes it possible to limit the distortions linked to the edge effects.

### SUMMARY OF THE INVENTION

The invention offers a solution to the problems mentioned hereinabove, by making it possible, using radial symmetry basis functions, to overcome the use of a meshing. In addition, so as to limit the edge effects, the invention proposes to extend the data along the sub-variety in the original space, as well as in the representation space.

For this, a first aspect of the invention relates to a method for determining the state of a system among a plurality of states, comprising a step of acquiring a plurality of values of at least one reference physical quantity of the system corresponding to a plurality of points in an original space, each value of the plurality of values being paired with one point of the plurality of points and with one state of the system;
a step of embedding at least one portion of the points of the plurality of points, called the embedded portion, in a representation space, this representation space being in bijection with a sub-variety of the original space, each point in the representation space thus obtained being paired with one state of the plurality of states of the system.

The method according to a first aspect of the invention further comprises:
a step of determining a function, called the pairing function, that pairs any position of the original space with a position in the representation space, the pairing function being obtained by interpolation by means of a radial symmetry basis function;
a step of determining, using the pairing function, the position in the representation space of at least one point of the original space paired with a value acquired a posteriori;
a step of determining the state of the system from the position of the point paired with the acquired value a posteriori in the representation space.

“Point of the original space paired with an acquired value a posteriori” means the fact that the point in question is separate from the data used to carry out the initial embedding. Thus, at the end of the method according to a first aspect of the invention, the state of the system is known without it being necessary to have recourse to a method of embedding for the point corresponding to the value acquired a posteriori. Not having recourse to an embedding makes it possible to reduce the calculation time required for determining the state of the system and thus to be able to carry out the monitoring in real time of said system. This also results in a method for determining the state of a system that consumes a less substantial amount of energy than with the methods of the state of the prior art, as the calculation resources used are less. This technical advantage makes it possible in particular to be able to consider the use of such a method in so-called embedded electronics.

In addition to the characteristics that have just been mentioned in the preceding paragraph, the method according to a first aspect of the invention can have one or more additional characteristics among the following, taken individually or according to any technically permissible combinations.

In an embodiment, the step of determining the pairing function comprises:
a substep of determining the value of the kernel φⱼ(Xᵢ^{app}) for the pair (i,j) using the following formula:

$${φ}_{j} ( {X}_{i}^{app} ) = φ ( \frac{D ( {X}_{i}^{app} , {X}_{j}^{app} )}{{σ}_{i}} )$$

where Xₙ^{app} is the n^{th} learning point with n∈ [symbol] 1; N [symbol] with N the number of learning points, φ radial symmetry basis functions, σⱼ is a scale parameter and D(Xᵢ^{app}, Xⱼ^{app}) the distance between the point i and the point j belonging to the plurality of points of the original space;
for each dimension of the representation space, a substep of determining coefficients C_{i,k} and a polynomial P(Xᵢ^{app}) using the following equation system: x_{i,k}^{app}=Σⱼφⱼ(Xᵢ^{app})×C_{j,k}+P(Xᵢ^{app}) where x_{i,k}^{app} is the coordinate of the i^{th} point of the original space on the k^{th} dimension of the representation space, the position of a point in the representation space, for each dimension of the representation space, being given by:

$${x}_{k}^{AP} = {\sum }_{j} {φ}_{j} ( {X}^{AP} ) + P ( {X}^{AP} )$$

where X^{AP} is the point in the original space to be positioned a posteriori and xₖ^{AP} is the coordinate of the point to be positioned on the k^{th} dimension of the representation space.

In an embodiment, the radial symmetry basis functions φ are chosen from a Gaussian kernel or a Matern kernel.

In an embodiment, the points of the plurality of points occupy an area in the representation space and in the original space and the method further comprises, after the step of embedding at least one portion of the points of the plurality of points, a step of extending the area occupied by the points in the representation space and in the original space.

This step of extending makes it possible to limit the edge effects and improve the accuracy and robustness of the positioning of the measurements a posteriori in the representation space and therefore the determining of the state of the system.

In an embodiment, the step of extending the area occupied by the points in the representation space and in the original space comprises:
a substep of determining at least one point of the representation space, called considered point of the representation space, located at the boundary of the sub-variety of the representation space, said boundary being defined locally for each point of the sub-variety; and
a substep of determining, from each considered point of the representation space and from at least one of its closest neighbours, a new point in the representation space, said new point in the representation space being retained if the latter is located beyond said boundary defined with respect to the considered point;
a substep of determining, from each point of the original space corresponding to the considered point in the representation space and at least one of its closest neighbours, a new point in the original space.

In an embodiment, the step of extending the area occupied by the points in the representation space and in the original space comprises, after the substep of determining a new point in the representation space and before the substep of determining a new point in the original space paired with its equivalent in the representation space, a substep of determining, the point located in the original space, called considered point of the original space, corresponding to the considered point in the representation space.

In an embodiment, the number of closest neighbours considered is less than or equal to 5.

In an embodiment, the method includes, when at least two new points are separated by a distance less than or equal to a predefined value d_{inf}, a step of merging said points.

A second aspect of the invention relates to a device for measuring the state of a physical system comprising a means of calculating and one or more sensors configured to acquire a plurality of values of at least one reference physical quantity of the system and to transmit said values to the means for calculating, said device being characterised in that the means for calculating is configured to implement a method according to a first aspect of the invention.

A third aspect of the invention relates to a computer program comprising program code instructions for executing steps of the method according to a first aspect of the invention when said program is executed on a computer.

A fourth aspect of the invention relates to a support that can be read by a computer, on which the computer program is recorded according to a third aspect of the invention.

The invention and its various applications shall be better understood when reading the following description and when examining the accompanying figures.

### BRIEF DESCRIPTION OF THE FIGURES

The figures are shown for the purposes of information and in no way limit the invention.

FIG. 1 shows a flowchart of a method according to a first aspect of the invention.

FIG. 2 shows a diagrammatical representation of a set of batteries whereon a method is applied according to a first aspect of the invention;

FIG. 3 shows a 2D and 3D diagrammatical representation of a step of extending sub-varieties according to a first aspect of the invention.

### DETAILED DESCRIPTION

Unless mentioned otherwise, the same element that appears on different figures has a unique reference.

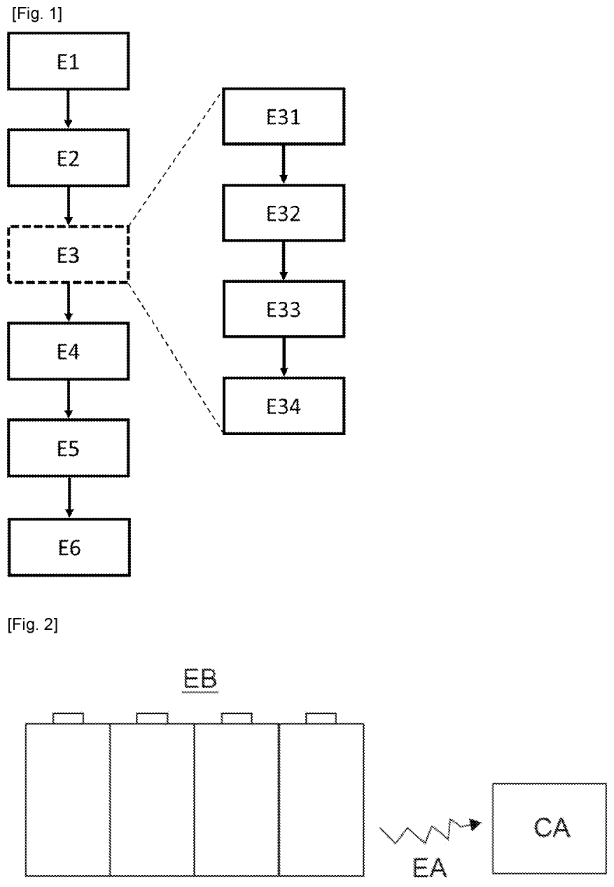

FIG. 1 shows a flowchart of an embodiment of a method 100 for determining the state of a system from a plurality of states according to a first aspect of the invention.

Acquisition of the Data

The method 100 comprises a step E1 of acquiring a plurality of values of at least one reference physical quantity of the system corresponding to a plurality of points in an original space, each value of the plurality of values being paired with one point of the plurality of points and with one state of the system. “Reference physical quantity of a system” means a physical quantity of which the value makes it possible, alone, to determine the state of a system. This physical quantity can be simple (for example the frequency or the amplitude paired with an acoustic emission) or composite (for example the frequency and the amplitude paired with an acoustic emission).

FIG. 2 shows an embodiment wherein the system takes the form of a set of batteries EB, a set of batteries EB able to comprise one or more batteries. The method according to a first aspect of the invention then consists of a method for determining the state of a set of batteries EB. The reference physical quantity can then consist of an acoustic emission EA. The method for determining the state of the set of batteries EB therefore comprises a step E1 of acquiring a plurality of acoustic emission recordings EA of the set of batteries EB, each recording being paired with a point in an original space and with a known state of the set of batteries. This acoustic recording can for example be carried out using an acoustic sensor CA.

Indeed, when a set of batteries EB is operating, it emits “sounds” and analysing these acoustic emissions makes it possible to determine the state of the set of batteries EB. For this the acoustic emission EA measured is broken down using a Fourrier series and each measurement is represented by a point the coordinates of which are given by the different frequencies measured and the amplitudes paired with these frequencies. The points thus obtained are then located in a first space of large dimension. In other words, the acoustic emissions EA of the set of batteries EB constitute a reference physical quantity in terms of the invention and each measured value of this reference physical quantity is paired with a point in an original space of large dimension.

Embedding a Portion at Least of the Data Acquired

The method also comprises a step E2 of embedding at least one portion of the points of the plurality of points, called the embedded portion, in a representation space, this representation space being in bijection with a sub-variety of the original space and defining a sub-variety in the representation space, each point in the representation space thus obtained being paired with one state of the plurality of states of the system.

The method of embedding used during this step E2 of embedding being a non-linear method, the embedding is necessarily carried out once the plurality of values of the reference physical quantity acquired. In other words, if the embedding is carried out then a new value is acquired, the plurality of values must again be embedded. The choice of the method of embedding used depends in particular on the system of which it is sought to determine the state and physical quantity measured for determining this state. Mention can be made for example of the Classical MDS (Classical Multi-Dimensional Scaling) method, the ISOMAP (Isometric Mapping) method, the CCA (Curvilinear Component Analysis) method and the set of methods of the non-metrics MDS (Non-Metric Multi-Dimensional Scaling) type.

In an embodiment, the method relates to determining the state of a set of batteries and comprises a step E2 of embedding at least one portion of the points paired with the acoustic recordings in a representation space, this representation space being in bijection with a sub-variety of the original space, said sub-variety able to be two-dimensional in the case of the set of batteries EB. In addition each point of this representation space is paired with a known state of the set of batteries EB.

Once the set of points is embedded in the representation space, a plurality of points in the representation space is obtained, each one of these points being paired with a known state of the set of batteries EB. In other words a map of the states of the set of batteries EB in the representation space is carried out. In the case of a set of batteries EB, the method of embedding must more preferably be chosen from the methods that preserve the neighbourhood relationships. The advantages of using this type of embedding are in particular detailed in the document “Mapping from the neighbourhood network”, Neurocomputing, vol. 72 (13-15), pp. 2964-2978.

Extending the Sub-Variety

In an embodiment, the method according to a first aspect of the invention comprises, after the step E2 of embedding at least one portion of the points of the plurality of points, a step E3 of extending the area occupied by the points in the representation space and in the original space. This step E3 of extending makes it possible to limit the edge effects. Indeed, the representation space is assimilated with a sub-variety of the original space, this sub-variety passing through the areas occupied by the data. In addition, any point of the original space is paired with a unique point in the representation space. If this relation is trivial when the considered point in the original space is located on the sub-variety and relatively simple to define when the point is located in the vicinity, it is on the other hand increasingly uncertain when the point moves away therefrom. Thus, a portion of the space (the areas populated by the data) is considered as well known, contrary to the rest of the space. The estimation of the sub-variety can be seen as a first approximation as an interpolation in the known portion (which is relatively simple), but also as an extrapolation in the rest of the space (which is much less simple). However, although it is unlikely that the data to be positioned a posteriori is located far from the sub-variety, it is an area where this is statistically probable: in the sub-variety, at the boundary of the populated area. The extending set up in the present invention makes it possible to reinforce the knowledge of the peripheral areas of the sub-variety of the representation space and to render the method of estimating the state of the system more robust, the populating of the periphery of the data making it possible to offer a continuity at the edge of the representation space in such a way as to guarantee the correct determining a posteriori of the position of the point in the representation space.

In an embodiment, the step E3 of extending the area occupied by the points in the representation space and in the original space comprises:
a substep E31 of determining at least one point of the representation space, called considered point of the representation space, located at the boundary of the sub-variety of the representation space, said boundary being defined so locally for each point of the sub-variety; and
a substep E32 of determining, from each considered point of the representation space and from at least one of its closest neighbours, a new point in the representation space, said new point in the representation space being retained if the latter is located beyond said boundary defined with respect to the considered point;
a substep E34 of determining, from each point of the original space corresponding to the considered point in the representation space and at least one of its closest neighbours, a new point in the original space.

It is important to note that the boundary used is a boundary determined locally according to the considered point and its closest neighbours. The position of the boundary is therefore a local property.

In an embodiment, the step E3 of extending the area occupied by the points in the representation space and in the original space comprises, after the substep E32 of determining a new point in the representation space and before the substep E34 of determining a new point in the original space paired with its equivalent in the representation space, a substep E33 of determining, the point located in the original space, called considered point of the original space, corresponding to the considered point in the representation space. In an embodiment, the number of closest neighbours considered is less than or equal to five.

It may occur however that this extending results in an excessive concentration of potentially contradictory points in an area outside the area of the space populated by the original data. In order to overcome this, in an embodiment, when at least two new points are separated by a distance less than or equal to a predefined value d_{inf}, the method according to a first aspect of the invention comprises a step of merging said points. More particularly, the points that are the closest to one another are deleted to the benefit of their barycentre. Initially each point has an identical weight, and when two points are merged, their weights are added together. The merge process is iterated until the two closest added points are at a distance greater than d_{inf}. In an embodiment, d_{inf} is defined as being the median of the distances of the points to their closest neighbours. Naturally, such a merger of points is implemented in the original space and in the representation space.

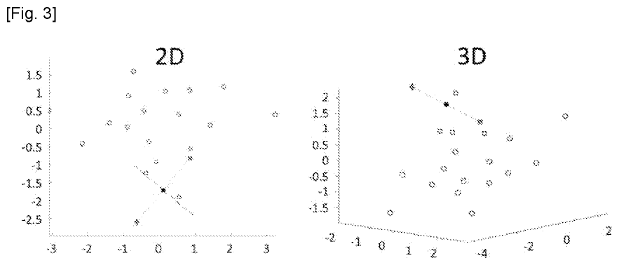

FIG. 3 shows an embodiment wherein, for a point xᵢ (represented by a solid circle) and the set of its k nearest neighbours {xⱼ}_{j∈n}_{ᵢ}_{([1;k])} (represented by squares), the point xᵢ is considered as being at the boundary of the representation space for a neighbourhood k if there is at least one neighbour x₁ (represented by the square on which the cross is centred), j∈nᵢ([1; k]), for which the set of the k nearest neighbours are on the same side of the hyperplane (in 2D, the hyperplane is represented by the dashed straight line—for reasons of clarity, the latter is not shown in 3D) passing through xᵢ normal to the straight line defined by xᵢ and xⱼ. The neighbours xⱼ that satisfy this constraint are said to be “able to be symmetrised” from the standpoint of xᵢ in what follows.

In what follows, vᵢ designates the bijection that at any k between 1 and N−1 pairs the index j=vᵢ(k) of the eh neighbour Xⱼ of the point Xᵢ in the original space. And likewise, in the representation space, the bijection nᵢ is defined for which, the point xₙ_{ᵢ}₍ₖ₎ is the k^{th} neighbour of the point xᵢ and dᵢₙ_{ᵢ}₍ₖ₎ is the distance that separates them in the representation space.

For any point at the periphery xᵢ and for any point xⱼ that can be symmetrised with respect to xᵢ, an extension point is constructed of the domain xᵢⱼ′ (represented by a diamond) defined by:

$${x}_{j}^{′} = {x}_{i} + \frac{{x}_{i} - {x}_{j}}{‖ {x}_{i} - {x}_{j} ‖} max ( min ( ‖ {x}_{i} - {x}_{j} ‖ , {d}_{sup} ) , {d}_{inf} )$$

where d_{inf}=Median_{i∈[1;N]}(dᵢₙ_{ᵢ}₍₁₎) and dₛᵤₚ=median_{i∈[1;N]}(dᵢₙ_{ᵢ}₍ₖ₎) where dᵢₙ_{ᵢ}₍ₖ₎ is the distance between the point xᵢ and are k^{th} nearest neighbour (noted as xₙ_{ᵢ}₍ₖ₎ in the representation space.

Note that any new point xᵢⱼ′, distant by less than d_{inf} from one of the k nearest neighbours of xᵢ, is rejected in order to prevent these new added points from having excessive influence on the areas populated by the original data.

For any extension point of the domain xᵢⱼ′, the equivalent process is applied to construct a paired extension point Xᵢⱼ′, in the original space, defined by:

$${X}_{ij}^{′} = {X}_{i} + \frac{{X}_{i} - {X}_{j}}{‖ {X}_{i} - {X}_{j} ‖} max ( min ( ‖ {X}_{i} - {X}_{j} ‖ , {D}_{sup} ) , {D}_{inf} )$$

With D_{inf}=median_{i∈[1;N]}(Dᵢᵥ_{ᵢ}₍₁₎) and Dₛᵤₚ=median_{i∈[1;N]}(Dᵢᵥ_{ᵢ}₍ₖ₎ where Dᵢᵥ_{ᵢ}₍ₖ₎ is the distance between the point Xᵢ and its k^{th} closest neighbour (noted as Xₙ_{ᵢ}₍ₖ₎ in the original space of the data).

It is understood that the example given hereinabove is only one method among several for constructing new points outside the domain of knowledge and it constitutes only an example, as many alternatives can be considered. It is also important to recall here that the boundary is a local boundary defined for a given point according to its nearest neighbour or neighbours. Methods other than the one presented here can be considered for determining this local boundary. The latter can for example be determined by the so-called lasso method. It is also possible to consider a method wherein the boundary is defined by the smallest convex polygon (i.e. convex envelope), by the set of triangles of a Delaunay graph amputated of their upper edges at a given distance or by the surface obtained by the “alpha shape” algorithm, etc.

The reference points obtained at the end of these two steps, or these three steps when there is an extending of the sub-variety, are intended to be compared to other values of the reference physical quantity obtained during later measurements. It is therefore important to be able to add points in the representation space so as to allow for said comparison. However, as was reminded hereinabove, such an adding would normally require to again embed the set of points paired with the values of the reference physical quantity acquired given that the method of embedding used is a non-linear method. In order to overcome this obstacle, two methods for positioning a posteriori a point of the original space in the representation space are proposed.

First Method for Positioning a Posteriori

A first way of doing this is to proceed as described in patent application no. FR 1663011 (published under number FR3060794), namely construct a lattice in the original space and in the representation space.

For this, in this embodiment, the method comprises a step of creating a first meshing in the representation space, called projection meshing, the meshes of said meshing being simplexes. The method also comprises a step of creating a second meshing in bijection with the projection meshing in the original space, referred to as original meshing, each mesh of the projection meshing being paired with a mesh of the original meshing. These two steps aim to produce a paving formed of regular simplexes (i.e. equilateral triangles if the map is 2D) on the data map. The positions of the vertices of the set of simplexes are then considered and values in each dimension are proposed from their positions, from the position of the data on the map and from values paired with the data for the dimension considered in the original space. Thus, it is possible to pair with each vertex in the map a point in the original space of the data and to produce the associated lattice.

Advantageously, the method comprises estimating the point density according to the area of the lattice in such a way as to deduce therefrom a probability for each new point of belonging to the area. This step makes it possible to limit the risk that a point is positioned in an unlikely area, such as the periphery of the map. These first two steps are calculations to be done before positioning new points. For more details, the reader can refer to patent application no. FR 1663011.

Second Method for Positioning a Posteriori

A second way of doing this is to have recourse to a RBF (radial symmetry basis functions) method in order to determine a function that makes it possible to pair a position (and therefore a point) of the original space with a position (and therefore a point) in the representation space. This method makes it possible to overcome the step of paving of the space by the triangle lattice and the step of calculating projections. In other words, the method according to the invention makes it possible to carry out in one step the projection and the interpolation. Indeed, the RBFs make it possible to calculate the position in the representation space of new points obtained during a measurement of at least one reference physical quantity by a simple linear algebra calculation. Thus, compared to the method of application no. FR 1663011, the calculation times are considerably reduced, which makes it possible to improve the quality of the monitoring of the state of the system considered.

For this, the method according to the invention comprises a step of determining a function, called the pairing function, that pairs any position of the original space with a position in the representation space, the pairing function being obtained by a resolution with radial symmetry basis functions.

In an embodiment, this step comprises a substep of determining the value of the kernel φⱼ(Xᵢ^{app}) for the pair(i, j) using the following formula:

$${φ}_{j} ( {X}_{i}^{app} ) = φ ( \frac{D ( {X}_{i}^{app} , {X}_{j}^{app} )}{{σ}_{i}} )$$

where Xₙ^{app} is the n^{th} learning point with n∈ [symbol] 1; N [symbol] (N the number of learning points), φ radial symmetry basis functions, σⱼ is a scale parameter and D(Xₜ^{app}, Xⱼ^{app}) the distance between the point i and the point j belonging to the plurality of points of the original space. The scale parameter σⱼ is preferably a parameter that can be set uniformly or adaptatively to the neighbourhood of the point Xⱼ^{app}. The radial symmetry basis functions φ can for example be chosen from the Gaussian kernel, a Matern kernel, etc. It is interesting to note that the metric used is not necessarily Euclidean. Indeed, many so-called non-linear mapping methods are able to process data of which the original space is not Euclidean. Most of the time however, the representation space is indeed Euclidean although this is not indispensable. In this case, it is natural to calculate the distance D(Xᵢ^{app}, Xⱼ^{app}) according to the metric of the original space, but it is also possible to use a different norm.

In an embodiment, the value of the kernel φⱼ(Xᵢ^{app}) for the pair (i,j) is determined using the following formula:

$${φ}_{j} ( {X}_{i}^{app} ) = exp ( - \frac{D ( {X}_{i}^{app} , {X}_{j}^{app} )}{{σ}_{j}} )$$

This step also comprises, for each dimension of the representation space, a substep of determining coefficients C_{i,k} and the polynomial P(Xᵢ^{app}) using the following equation: x_{i,k}^{app}=Σⱼφⱼ(Xᵢ^{app})×C_{j,k}+P(Xᵢ^{app}) where x_{i,k}^{app} is the coordinate of the i^{th} point of the original space on the k^{th} dimension of the representation space. The values of the coefficients C_{i,k} thus obtained belong to a matrix of which the number of lines is equal to the number of learning data points (i.e. the number of points of the portion of the plurality of points) and the number of columns is equal to the dimension of the representation space. In this example, it is assumed that the matrix φⱼ(Xₜ^{app}) is invertible. In practice, it is even desirable for its conditioning to not be excessively high with regards to the machine precision.

The coefficients C_{i,k} and the polynomial thus obtained make it possible to pair with any point of the original space, a point of the representation space. In other words, when a new measurement of the reference physical quantity is taken and paired with a point of the original space, the position of this point of the original space in the representation space can then be determined, the coordinates of the point in the representation space being calculated using coefficients C_{j,k} and the polynomial P(Xᵢ^{app}). More particularly, the position of a point in the representation space, for each dimension of the representation space, is given by:

Xₖ^{AP}=Σⱼφⱼ(X^{AP})C_{j,k}+P(X^{AP})

where X^{AP} is the point of the original space to be positioned a posteriori and xₖ^{AP} is the coordinate of the point to be positioned on the k^{th} dimension of the representation space. This calculation is very fast because it is direct (it does not require any interpolation) and it is easy to simultaneously calculate the position of a high number of data by means of a matrix calculation. Furthermore, as explained hereinabove, this determining is carried out a posteriori, i.e. without having recourse to another embedding of the set of points of the original space in the representation space.

The use of radial symmetry basis functions allows for an interpolation of a target value in a space. Here, the space considered is the original space and the target value is one of the dimensions of the representation space. This interpolation is repeated for each dimension of the representation space. So, after resolution, an application of the original space towards the representation space is obtained. It is important to note that this application is continuous and gives an exact result (to the nearest machine error) for the initially projected points.

The steps of the method according to a first aspect of the invention that have just been described make it possible in particular to:
obtain reference points in an original space and embed them in a representation space in order to obtain a map of the states of the system in the representation space;
possibly, extend the domain of knowledge paired with the reference points, so as in particular to limit the edge effects in the determining of the methods for positioning a posteriori;
for the first method for positioning a posteriori, set up a projection meshing in the representation space, as well as an original meshing in the original space which is the mirror of it in such a way that there is a bijection between the vertices of the simplexes in the two spaces, this bijection able to be used in order to determine the position of the image of a point of the original space in the representation space;
for the second method of positioning a posteriori, determine a pairing function that makes it possible to determine the position of the image of a point of the original space in the representation space.

Once these various elements are in place, it is possible to position the point of the original space paired with a measurement acquired in the representation space without having recourse to an embedding.

Positioning a Posteriori Using the First Method of Positioning a Posteriori

In order to take advantage of the first method for positioning a posteriori, the method then comprises an orthogonal projection step on the original meshing of at least one point paired with an acquired value, said point not belonging to the embedded portion. This acquired value is preferably acquired during the operation of the system in such a way as to be able to determine the state of said system. The method also comprises a step of determining the position of the image of said point in the projection meshing according to the position of the orthogonal projection of said point on the original meshing, in such a way as to obtain a point in the representation space and thus determine the state of the system. These two steps make it possible to position the new data. An orthogonal projection on each triangle of the lattice in the original space of the data is calculated. The proximity of the projection with the original point is used to calculate a neighbourhood probability between the point and its projection (the closer the points are, the higher the probability is). For more details, the reader can refer to patent application no. FR 1663011.

Positioning a Posteriori Using the Pairing Function

In order to take advantage of the pairing function, the method then comprises a step E5 of determining, using the pairing function, the position in the representation space of at least one point of the original space paired with an acquired value a posteriori. This value acquired a posteriori is preferably acquired during the operation of the system is such a way as to be able to determine the state of said system.

The method then comprises a step E6 of determining the state of the system from the position of the point paired with the acquired value a posteriori in the representation space.

In the case of a set of batteries, the method therefore comprises a step of determining, using the pairing function, the position in the representation space of at least one point of the original space paired with a newly-acquired acoustic emission. The method then comprises a step of determining the state of the set of batteries from the position of the point paired with the acoustic emission acquired in the representation space.

States and Classes of States

In an embodiment, each state of the system can be paired with a class of states from a plurality of classes of states, each value acquired during the first step E1 of acquiring a plurality of values being paired with a known class of states. In other words, different classes of states of the system are chosen of which it is sought to be able to determine the nature by later measurements and a plurality of acquisitions are carried out of the value of at least one reference physical quantity for each one of said classes of states. The method further comprises a step of determining the class of states of the system by comparison between the position of the point image in the representation space and the position of the points embedded in said representation space during the step E2 of embedding.

In an embodiment, the method of embedding used during the step E2 of embedding is a supervised method of embedding. For example, the method of embedding is the Classimap method. This in particular makes it possible to increase the coherency between the positions of the points and the class of states in the representation space coming from the step of determining the position of the point paired with the acquired value in the representation space.

The examples given hereinabove refer to a set of batteries, but a method according to a first aspect of the invention is adapted to any system that requires an embedding of points relative to measurements. For example the system can be relative to the tracing of a handwritten character. This type of problem is for example conventional in the field of automatically reading post codes by mail transport agencies or of cheques by banks. In this case here, each state of the system corresponds to a particular tracing and the reference physical quantity corresponds to the image of said tracing (the dimension of the original space is therefore according to the resolution of the image). In addition, the different states of the system can be attached to classes of state corresponding to different digits (or letters) paired with each tracing. For example, a first plurality of states (therefore tracings) can be paired with a first class of state (the digit 1 for example). The method for determining the state of a system can, in this case, constitute, using an embedding, a map in the representation space (for example a two-dimensional space) of the different states (different tracings) and of the different classes of states (different digits or letters) from a first step of acquiring a plurality of images, each image being paired with a state and with a class of states of the system. This map can be used by positioning a point in the representation space paired with a handwritten character by means of an original meshing and a projection meshing or then a pairing function, said point corresponding to a handwritten tracing of which the class of state is unknown, and this in order to identify the class of state (the digit or the letter) represented by said tracing. In other words, in this embodiment, a method according to a first aspect of the invention can also be implemented in order to identify the digit represented by a tracing from a photograph of said tracing and in particular implemented by a postal sorting apparatus or a bank cheque processing apparatus.

Device Implementing the Method According to the Invention

A second aspect of the invention relates to a device for measuring the state of a physical system. The device comprises a means of calculating (or calculator) and one or more sensors configured to acquire a plurality of values of a reference physical quantity of the system and to transmit said values to the means for calculating (or calculator). In addition the means for calculating (or calculator) is configured to implement a method according to a first aspect of the invention. The means for calculating can take the form of a processor paired with a memory, a FPGA (Field-Programmable Gate Array) or of a carte of the ASIC (Application-Specific Integrated Circuit) type.

1. A method for determining the state of a system among a plurality of states, comprising
a step of acquiring a plurality of values of at least one reference physical quantity of the system corresponding to a plurality of points in an original space, each value of the plurality of values being paired with one point of the plurality of points and with one state of the system;
a step of embedding at least one portion of the points of the plurality of points in a representation space, said representation space being in bijection with a sub-variety of the original space, each point in the representation space thus obtained being paired with one state of the plurality of states of the system;
a step of determining a pairing function that pairs any position of the original space with a position in the representation space, the pairing function being obtained by interpolation by means of radial symmetry basis functions;
a step of determining, by the pairing function, the position in the representation space of at least one point of the original space paired with an acquired value a posteriori;
a step of determining the state of the system from the position of the point paired with the acquired value a posteriori in the representation space.

2. The method according to claim 1, wherein the step of determining the pairing function comprises:
a substep of determining the value of the kernel φⱼ(xᵢ^{app}) for the pair(i, j) using the following formula:
$${φ}_{j} ( {X}_{i}^{app} ) = φ ( \frac{D ( {X}_{i}^{app} , {X}_{j}^{app} )}{{σ}_{i}} )$$
where Xₙ^{app} is the n^{th} learning point with n∈ [symbol] 1; N [symbol] N the number of learning points, φ radial symmetry basis functions, σⱼ is a scale parameter and D(Xᵢ^{app}, Xⱼ^{app}) the distance between the point i and the point j belonging to the plurality of points of the original space;
for each dimension of the representation space, a substep of determining a coefficient C_{i,k} and a polynomial P(Xᵢ^{app}) using the following equation: x_{i,k}^{app}=Σⱼφₐₚₚ(i,j)×C_{j,k}+P(Xᵢ^{app}) where X_{i,k}^{app} is the coordinate of the i^{th} point of the original space on the k^{th} dimension of the representation space, the position of a point in the representation space, for each dimension of the representation space, being given by:
$${x}_{k}^{AP} = {\sum }_{j} {φ}_{j} ( {X}^{AP} ) + P ( {X}^{AP} )$$
where X^{AP} is the point of the original space to be positioned a posteriori and xₖ^{AP} is the coordinate of the point to be positioned on the k^{th} dimension of the representation space.

3. The method according to claim 2, wherein the radial symmetry basis functions φ are chosen from a Gaussian kernel or a Matern kernel.

4. The method for determining the state of a system according to claim 1, wherein the points of the plurality of points occupy an area in the representation space and in the original space and in that wherein the method further comprises, after the step of embedding at least one portion of the points of the plurality of points, a step of extending the area occupied by the points in the representation space and in the original space.

5. The method according to claim 4, wherein the step of extending the area occupied by the points in the representation space and in the original space comprises:
a sub step of determining at least one considered point of the representation space located at the boundary of the sub-variety of the representation space, said boundary being defined locally for each point of the sub-variety; and
a substep of determining, from each considered point of the representation space and from at least one of its closest neighbours, a new point in the representation space, said new point in the representation space being retained when the latter is located beyond said boundary defined with respect to the considered point;
a substep of determining, from each considered point of the original space and from at least one of its closest neighbours, a new point in the original space paired with its equivalent in the representation space.

6. The method according to claim 5, wherein the step of extending the area occupied by the points in the representation space and in the original space comprises, after the substep of determining a new point in the representation space and before the substep of determining a new point in the original space paired with its equivalent in the representation space, a substep of determining the point located in the original space, called considered point of the original space, corresponding to the considered point in the representation space.

7. The method according to claim 5, wherein the number of closest neighbours considered is less than or equal to 5.

8. The method according to claim 7, comprising, when at least two new points are separated by a distance less than or equal to a predefined value d_{inf}, a step of merging said points.

9. A device for measuring the state of a physical system comprising a calculator and one or more sensors configured to acquire a plurality of values of at least one reference physical quantity of the system and to transmit said values to the calculator, said calculator being configured to implement a method according to claim 1.

10. Computer program comprising program code instructions for executing steps of the method according to claim 1 when said program is executed on a computer.

11. A non-transitory computer readable support readable by a computer, on which a computer program is recorded comprising program code instructions for executing steps of the method according to claim 1.
